(19) United States
(12) Patent Application Publication
(10) Pub. No.: US 2006/0043399 A1
(43) Pub. Date: Mar. 2, 2006

(54) Semiconductor light emitting device

(75) Inventors: Atsushi Miyagaki, Kanagawa-ken (JP); Kazuyoshi Furukawa, Kanagawa-ken (JP); Yasuharu Sugawara, Kanagawa-ken (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 11/208,654

(22) Filed: Aug. 23, 2005

(30) Foreign Application Priority Data
Aug. 24, 2004 (JP) 2004-243981

(51) Int. Cl. H01L 33/00

(52) U.S. Cl. 257/98; 257/103

(57) ABSTRACT

A semiconductor light emitting device comprises: a substrate; a light emitting layer; and an ohmic electrode. The substrate has first and second major surfaces and being transparent to light in a first wavelength band. The light emitting layer is provided above the first major surface of the substrate, and the light emitting layer emits light in the first wavelength band. The ohmic electrode is selectively embedded on the second major surface of the substrate and has a surface substantially coplanar with the second major surface.

### CROSS-REFERENCE TO RELATED APPLICATIONS

This application is based upon and claims the benefit of priority from the prior Japanese Patent Application No. 2004-243981, filed on Aug. 24, 2004; the entire contents of which are incorporated herein by reference.

### BACKGROUND OF THE INVENTION

1. Field of the Invention

This invention relates to a semiconductor light emitting device, and more particularly to a semiconductor light emitting device having improved extraction efficiency for light emitted from its active layer.

2. Background Art

Semiconductor light emitting devices such as LEDs (light emitting diodes) and LDs (laser diodes) can provide various emission wavelengths, high emission efficiency, and long lifetime while being compact in size. For this reason, they are widely used for display, lighting, communication, sensor, and other devices.

FIG. 29 is a schematic view showing an example cross-sectional structure of an LED.

A light emitting layer section 611 is provided on a semiconductor substrate 601 made of n-type GaAs. The light emitting layer section 611 is made of InGaAlP-based compound semiconductor and comprises an active layer 604 sandwiched between an n-type cladding layer 603 and a p-type cladding layer 605 having a larger band gap than the active layer 604. On the light emitting layer section 611 is provided a window layer 606. A p-side electrode 608 is provided on a contact layer 607 made of p-type GaAs, and an n-side electrode 609 is provided on the rear side of the semiconductor substrate 601.

This LED has the so-called “double heterostructure” in which the cladding layers 603 and 605 having a larger band gap are provided above and below the active layer 604. The LED can thereby efficiently confine carriers in the active layer 604 and emit light with high efficiency (Japanese Laid-Open Patent Application 2002-353502).

However, in the semiconductor light emitting device as illustrated in FIG. 29, the extraction efficiency for light emitted from the active layer 604 is not sufficiently high.

More specifically, since the GaAs substrate 601 has a smaller band gap than the InGaAlP active layer 604, light emitted from the InGaAlP active layer 604 in the direction indicated by arrow A is absorbed in the GaAs substrate 601, and thus cannot be extracted outside.

In order to avoid the optical absorption by a substrate, a LED having a transparent substrate formed by using a wafer-bonding technique is proposed. However, even in the case where the transparent substrate is employed, an optical absorption by an ohmic contact layer for a lower electrode occurs.

U.S. Pat. No. 5,917,202 discloses a semiconductor light emitting device having a transparent substrate with small alloyed dots provided on its rear side. In this semiconductor light emitting device, a metal layer is formed on the rear side of the GaP substrate and heated by laser irradiation in a dot pattern to form small alloyed dots. In this semiconductor light emitting device, ohmic contact is obtained at the small alloyed dots, whereas the remaining metal layer acts as a light reflecting film.

However, since the surface of the metal layer is locally irradiated with a strong laser beam, this structure is prone to residual stress and/or crystal defects in the GaP substrate. This may result in decreased emission brightness or degradation over time.

Additionally, in this structure, the metal layer has the same metal constituents as the small alloyed dots. More specifically, the small alloyed dots are formed by reaction of the metal layer with the GaP substrate where the laser struck. It is therefore difficult to achieve good ohmic contact and high reflectance at the same time. That is, metal having high photoreflectance is difficult to form ohmic contact, whereas metal being easy to form ohmic contact has poor photoreflectance.

As described above, conventional LEDs have room for improvement in the extraction efficiency for light emitted from the active layer.

### SUMMARY OF THE INVENTION

According to an aspect of the invention, there is provided a semiconductor light emitting device comprising:
a substrate having first and second major surfaces and being transparent to light in a first wavelength band;
a light emitting layer provided above the first major surface of the substrate, the light emitting layer emitting light in the first wavelength band; and
an ohmic electrode selectively embedded on the second major surface of the substrate and having a surface substantially coplanar with the second major surface.

According to other aspect of the invention, there is provided a semiconductor light emitting device comprising:
a substrate having first and second major surfaces and being transparent to light in a first wavelength band, the second major surface having steps with bottom, side, and top faces;
a light emitting layer provided above the first major surface of the substrate, the light emitting layer emitting light in the first wavelength band; and
an electrode selectively provided in contact with the side face of the steps.

According to other aspect of the invention, there is provided a semiconductor light emitting device comprising:
a substrate having first and second major surfaces and being transparent to light in a first wavelength band;
a light emitting layer provided above the first major surface of the substrate, the light emitting layer emitting light in the first wavelength band;
an electrode provided on the second major surface of the substrate;
a reaction suppressing film selectively provided between the second major surface of the substrate and the electrode, the reaction suppressing film suppressing reaction between the substrate and the electrode; and
a light reflecting film selectively embedded in the substrate, the light reflecting film reflecting light in the first wavelength band directed toward the interface between the substrate and the electrode as viewed from the light emitting layer.

### BRIEF DESCRIPTION OF THE DRAWINGS

FIG. 1 is a schematic view illustrating the cross-sectional structure of a semiconductor light emitting device according to a first embodiment of the invention;

FIG. 2 is a schematic view showing a semiconductor light emitting device of a comparative example investigated by the inventors in the course of reaching the invention;

FIGS. 3A and 3B are schematic cross-sectional views illustrating the semiconductor light emitting device of the first embodiment and of the comparative example mounted on a packaging member, respectively;

FIG. 4 is a schematic view showing the cross-sectional structure of another semiconductor light emitting device of the first embodiment;

FIGS. 5A to 7C are process cross-sectional views showing part of a process of manufacturing a semiconductor light emitting device of the first embodiment;

FIG. 8 is a schematic view illustrating the cross-sectional structure of a semiconductor light emitting device according to a second embodiment of the invention;

FIGS. 9 to 13 are schematic views illustrating a planar pattern configuration of the bottom face 32A or top face 32B;

FIG. 14 is a schematic view illustrating the cross-sectional structure of a variation of the semiconductor light emitting device according to the second embodiment;

FIGS. 15A to 16C are process cross-sectional views showing a method of manufacturing a semiconductor light emitting device of the second embodiment;

FIG. 17 is a schematic cross-sectional view showing a second example of the semiconductor light emitting device of the second embodiment;

FIG. 18 is an enlarged cross-sectional view of a relevant part intended for illustrating the function in the second example of the second embodiment;

FIG. 19 is a schematic cross-sectional view showing a third example of the semiconductor light emitting device of the second embodiment;

FIG. 20 is a schematic view showing the cross-sectional structure of a semiconductor light emitting device of a third embodiment of the invention;

FIG. 21 is a partially enlarged cross-sectional view of the semiconductor light emitting device of the third embodiment;

FIGS. 22A to 23C are process cross-sectional views illustrating a method of manufacturing a semiconductor light emitting device of the third embodiment;

FIG. 24 is a schematic cross-sectional view showing a semiconductor light emitting apparatus of an embodiment of the invention;

FIG. 25 is a schematic cross-sectional view showing another example of the semiconductor light emitting apparatus;

FIGS. 26 to 28 are schematic cross-sectional views showing still another example of the semiconductor light emitting apparatus; and

FIG. 29 is a schematic view showing an example cross-sectional structure of an LED.

### DETAILED DESCRIPTION OF THE INVENTION

Embodiments of the invention will now be described with reference to the drawings.

### First Embodiment

The first embodiment of the invention will be described with reference to a semiconductor light emitting device in which an electrode is selectively embedded in the rear side of a transparent substrate.

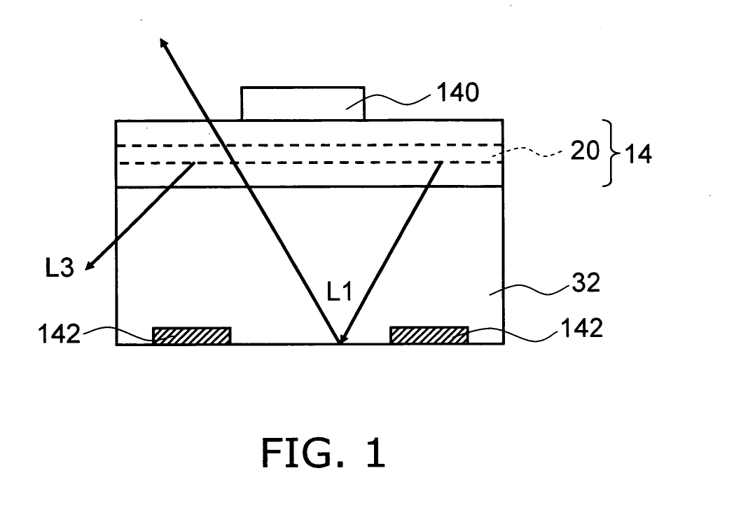

FIG. 1 is a schematic view illustrating the cross-sectional structure of a semiconductor light emitting device according to this embodiment.

More specifically, the semiconductor light emitting device has a substrate 32 and a light emitting layer 14 provided thereon. The substrate 32 is made of material being transparent to the light emitted from the light emitting layer 14. An electrode 140 is provided on top of the light emitting layer 14. Another electrode 142 is selectively embedded in the rear side of the substrate 32. In this embodiment, one of the electrodes 140 and 142 is a p-side electrode, and the other is an n-side electrode.

In this embodiment, the substrate 32 is formed from material being transparent to the light emitted from the light emitting layer 14. Therefore light can also be extracted from the side face of the substrate 32. More specifically, light L3 emitted downward from the light emitting layer 14 travels through the substrate 32 and exits from its side face. Thus the light extraction efficiency can be increased.

Additionally, in this embodiment, the electrode 142 is selectively provided on the rear face of the substrate 32. Therefore absorption of light at the rear face of the substrate 32 can be reduced. More specifically, the electrode 142 is typically doped with dopants for achieving ohmic contact with the substrate 32. The dopants diffuse into the substrate 32 to form a high-concentration region. Furthermore, the electrode 142 is often alloyed with the substrate 32 by heat treatment (sintering). The high-concentration region and alloyed region absorb light emitted from the light emitting layer 14, thereby causing some loss.

In contrast, according to this embodiment, by selectively providing the electrode 142, formation of the high-concentration region and alloyed region can be prevented in the area other than the electrode 142. As a result, photoreflectance at the rear side of the substrate 32 is increased. That is, light L1 emitted downward from the light emitting layer 14 can be reflected at the rear face of the substrate 32 and extracted from the side face and/or top face of the device.

Furthermore, according to this embodiment, by embedding the electrode 142, the rear side of the device can be made flat, thereby improving heat contact with a packaging member.

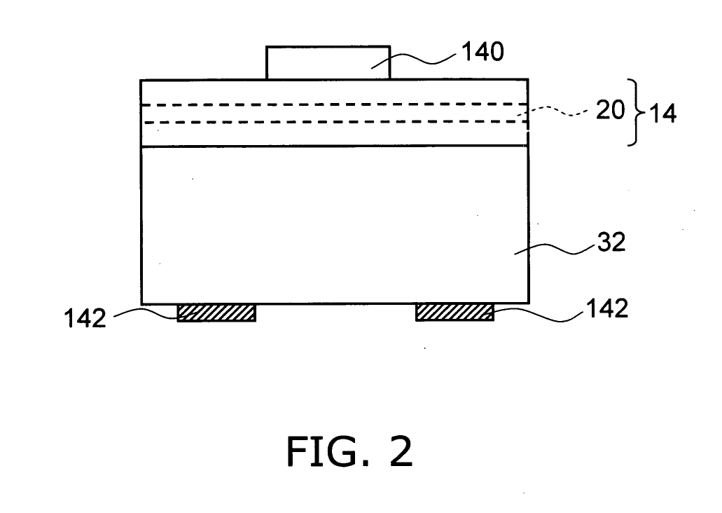

FIG. 2 is a schematic view showing a semiconductor light emitting device of a comparative example investigated by the inventors in the course of reaching the invention. More specifically, in this light emitting device, the electrode 142 is not embedded in the substrate 32, but protrudes from the rear side.

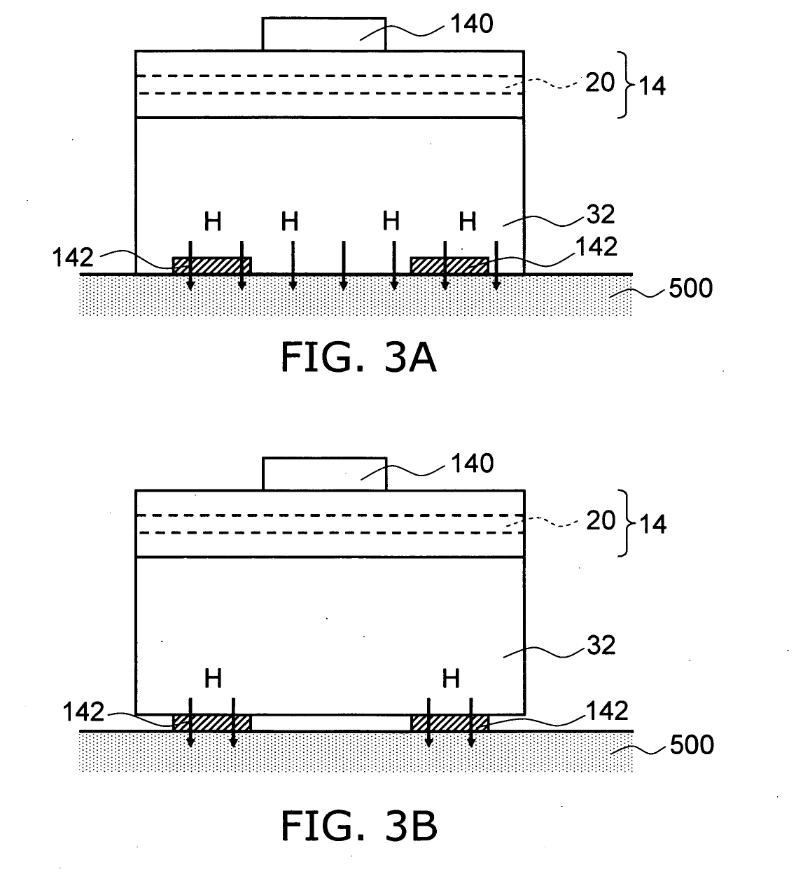

FIGS. 3A and 3B are schematic cross-sectional views illustrating the semiconductor light emitting device of this embodiment and of the comparative example mounted on a packaging member, respectively. The semiconductor light emitting device is mounted on a packaging member 500 such as a lead frame, stem, or mounting board using solder or a conductive adhesive.

In the comparative example, as shown in FIG. 3B, steps corresponding to the thickness of the electrode 142 are formed on the rear face of the device. As a result, it is likely to develop regions having insufficient heat contact between the substrate 32 and the packaging member 500. That is, the path of heat dissipation from the semiconductor light emitting device to the packaging member 500 is limited to only the vicinity of the electrode 142 as shown by arrow H in this figure. Decrease of heat contact causes increase of temperature of the semiconductor light emitting device, which may result in the decrease of emission efficiency, deviation of emission wavelength, and/or decrease of reliability including lifetime. These problems are significant especially in light emitting devices such as high-power LEDs.

In contrast, according to this embodiment, the electrode 142 is embedded in the substrate 32. Therefore, as shown in FIG. 3A, the rear face of the substrate 32 is nearly entirely in contact with the packaging member 500, and thereby heat contact can be improved. That is, as shown by arrow H in this figure, heat dissipation can be caused to occur throughout the surface of the substrate 32. As a result, the temperature increase of the device can be reduced, and the initial characteristics and the reliability can be improved.

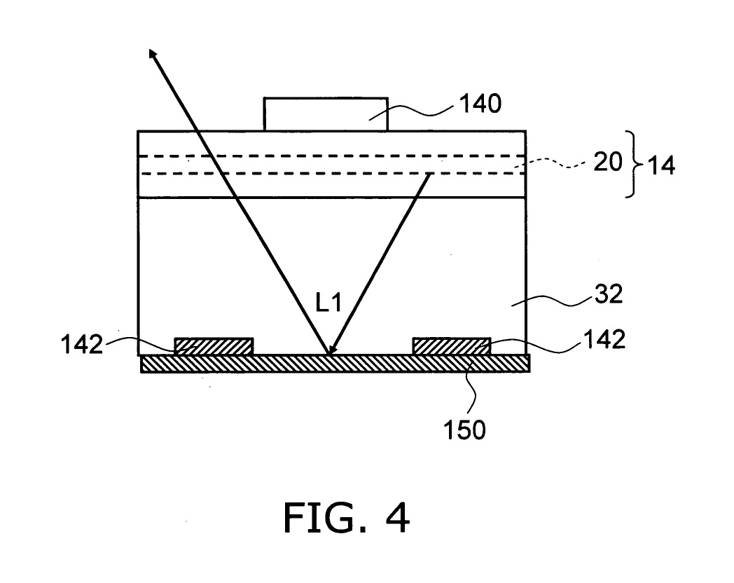

FIG. 4 is a schematic view showing the cross-sectional structure of another semiconductor light emitting device of this embodiment.

More specifically, in this semiconductor light emitting device, the electrode 142 is selectively embedded in the rear side of the substrate 32, and a conductive reflecting film 150 is further provided on the rear face of the substrate 32. The conductive reflecting film 150 can be formed from metal such as gold (Au), for example.

The conductive reflecting film 150 can improve not only heat contact, but also reflectance for light L1 emitted from the light emitting layer 14, thereby further increasing the light extraction efficiency. In order to increase the reflectance for light L1, the conductive reflecting film 150 is preferably formed from material that does not have excessively high reactivity with the substrate 32.

In this structure, the ohmic electrode 142 and the reflecting film 150 can be formed from different metal materials. Therefore good ohmic contact and high photoreflectance can be definitely and easily achieved.

Furthermore, according to this structure, by embedding the ohmic electrode 142 in the substrate 32, the rear side thereof can be made substantially flat. Therefore the surface of the reflecting film 150 can be made flat even for a small film thickness of the reflecting film 150. This facilitates achieving good heat contact when the device is mounted on the packaging member.

The semiconductor light emitting device of this embodiment as described above with reference to FIGS. 1 to 4 is applicable to light emitting devices made of various material systems, including InGaAlP-based and GaN-based light emitting devices, for example.

Next, this embodiment is applied to an InGaAlP-based light emitting device, which is used as an example for describing a method of manufacturing the same.

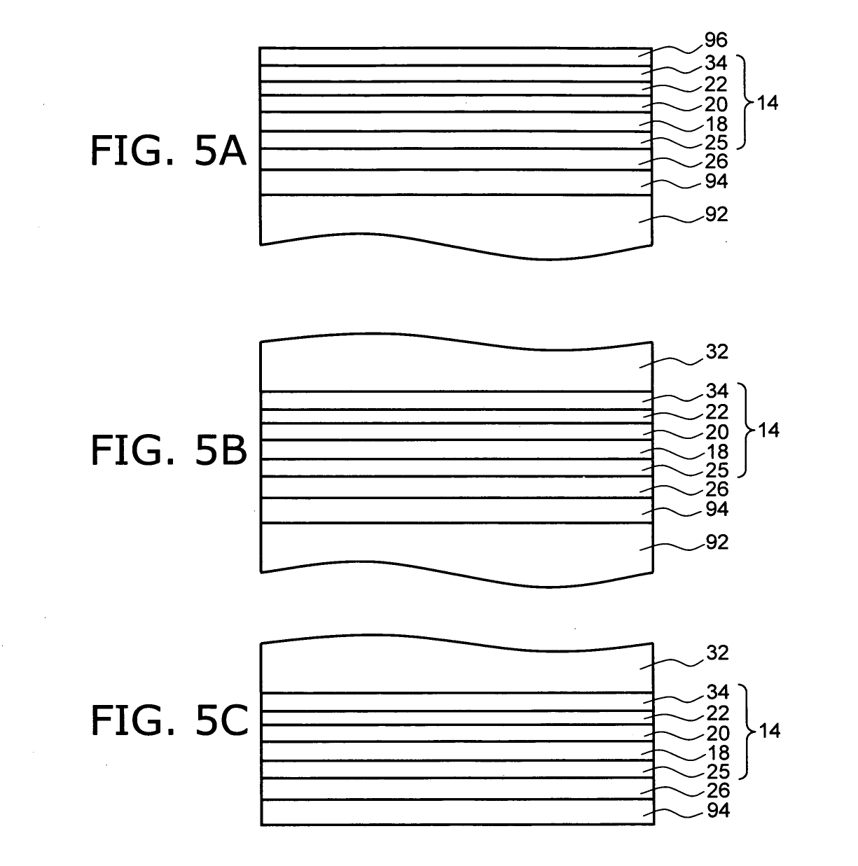

FIGS. 5A to 7C are process cross-sectional views showing part of a process of manufacturing a semiconductor light emitting device of this embodiment.

First, as shown in FIG. 5A, an InAlP etch stop layer 94, GaAs contact layer 26, InGaAlP current diffusion layer 25, n-type InGaAlP cladding layer 18, InGaAlP active layer 20, p-type InGaAlP cladding layer 22, InGaP bonding layer 34, and InAlP cover layer 96 are grown on an n-type GaAs substrate 92. The n-type GaAs substrate 92 may be a mirror-finished substrate having a diameter of 3 inches and a thickness of 350 μm, and doped with silicon (Si) at a carrier concentration of about 1×10¹⁸/cm³.

The etch stop layer 94 may have a thickness of 0.2 μm. The GaAs contact layer 26 has a thickness of 0.02 μm and a carrier concentration of 1×10¹⁸/cm³. The InGaAlP current diffusion layer 25 is made of InGaAlP with Al composition of 0.3 and may have a thickness of 1.5 μm. The n-type cladding layer 18 is made of InGaAlP with Al composition of 0.6 and may have a thickness of 0.6 μm. The active layer 20 is made of InGaAlP with Al composition of 0.04 and may have a thickness of 0.4 μm. The p-type cladding layer 22 is made of InGaAlP with Al composition of 0.6 and may have a thickness of 0.6 μm. The InGaP bonding layer 34 may have a thickness of 0.1 μm, and the InAlP cover layer 96 may have a thickness of 0.15 μm.

Next, this epitaxial wafer is washed with surfactant, immersed in a mixture of ammonia and hydrogen peroxide solution with a volume ratio of 1:15 to etch the rear side of the GaAs substrate 92, thereby removing any reaction byproducts and the like produced in the epitaxial growth and attached to the rear face of the epitaxial wafer.

Next, the epitaxial wafer is washed again with surfactant. The topmost InAlP cover layer 96 is then removed with phosphoric acid to expose the InGaP bonding layer 34.

Subsequently, as shown in FIG. 5B, a GaP substrate 32 is laminated. In the following, a process of direct bonding will be described in detail.

For the GaP substrate 32, a mirror-finished p-type substrate having a diameter of 3 inches and a thickness of 300 μm, for example, is used. A high-concentration layer may be formed on the surface of the GaP substrate 32 to lower the electric resistance at the bonding interface. As a preprocess for direct bonding, the GaP substrate 32 is washed with surfactant, immersed in dilute hydrofluoric acid to remove natural oxidation film on the surface, washed with water, and then dried using a spinner. With regard to the epitaxial wafer, after the cover layer 96 on the surface thereof is removed, it is treated with dilute hydrofluoric acid for removing oxidation film, washed with water, and spin-dried, in the same way as for the GaP substrate 32. Preferably, these preprocesses are entirely performed under a clean atmosphere in a clean room.

Next, the preprocessed epitaxial wafer is placed with the InGaP bonding layer 34 turned up, on which the GaP substrate 32 is mounted with its mirror surface turned down, and closely contacted together at room temperature.

Next, as a final step of direct bonding, the wafers contacted at room temperature are set up in a line on a quartz boat, and placed in a diffusion oven for heat treatment. The heat treatment may be performed at a temperature of 800° C. for a duration of one hour in an atmosphere of argon containing 10% hydrogen. This heat treatment integrates the GaP substrate 32 with the InGaP bonding layer 34, thereby completing the bonding.

Next, as shown in FIG. 5C, the GaAs substrate 92 of the epitaxial wafer is removed. More specifically, the bonded wafer is immersed in a mixture of ammonia and hydrogen peroxide solution to selectively etch the GaAs substrate 92. This etching step stops at the InAlP etch stop layer 94. Next, etching is performed with phosphoric acid at 70° C. to selectively remove the InAlP etch stop layer 94.

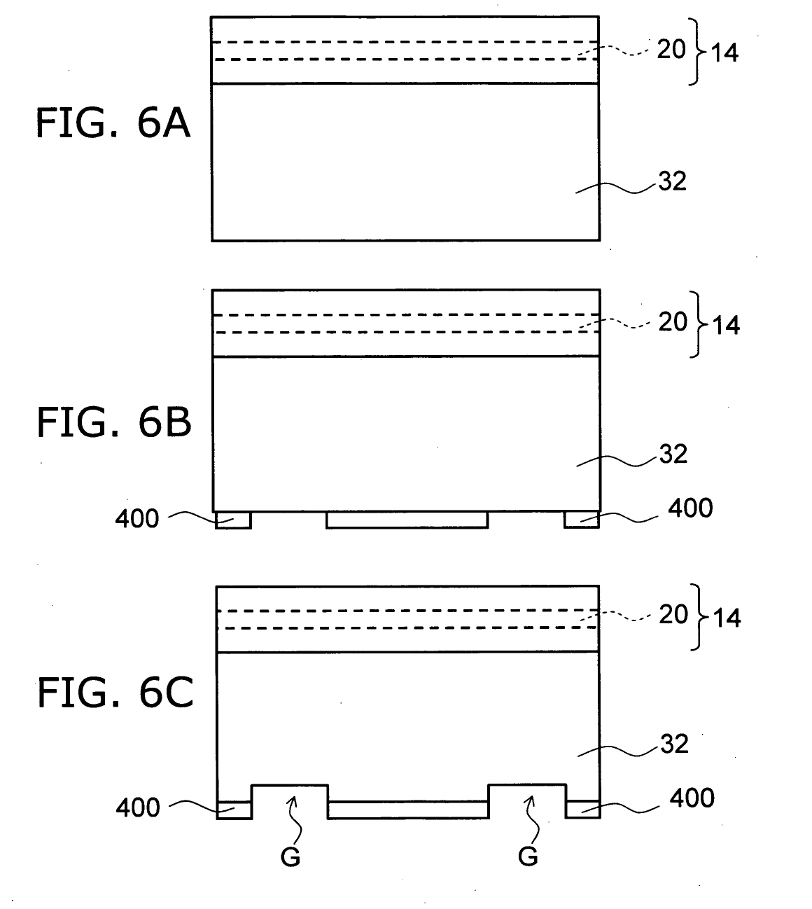

The foregoing process results in a bonded substrate for LED, as shown in FIG. 6A, in which the InGaAlP light emitting layer 14 is provided on the GaP transparent substrate 32.

Next, as shown in FIG. 6B, a mask 400 is provided on the rear side of the GaP substrate 32. The mask 400 has apertures at locations where an electrode is to be provided. For example, the aperture is circular with a diameter of 50 μm, and the apertures can be provided at a pitch of 100 μm vertically and horizontally. The mask 400 may be made of SiO₂ formed by CVD (chemical vapor deposition), for example.

Next, as shown in FIG. 6C, grooves G are formed on the rear face of the GaP substrate 32 by RIE (reactive ion etching). The groove may have a depth of 1.5 μm, for example.

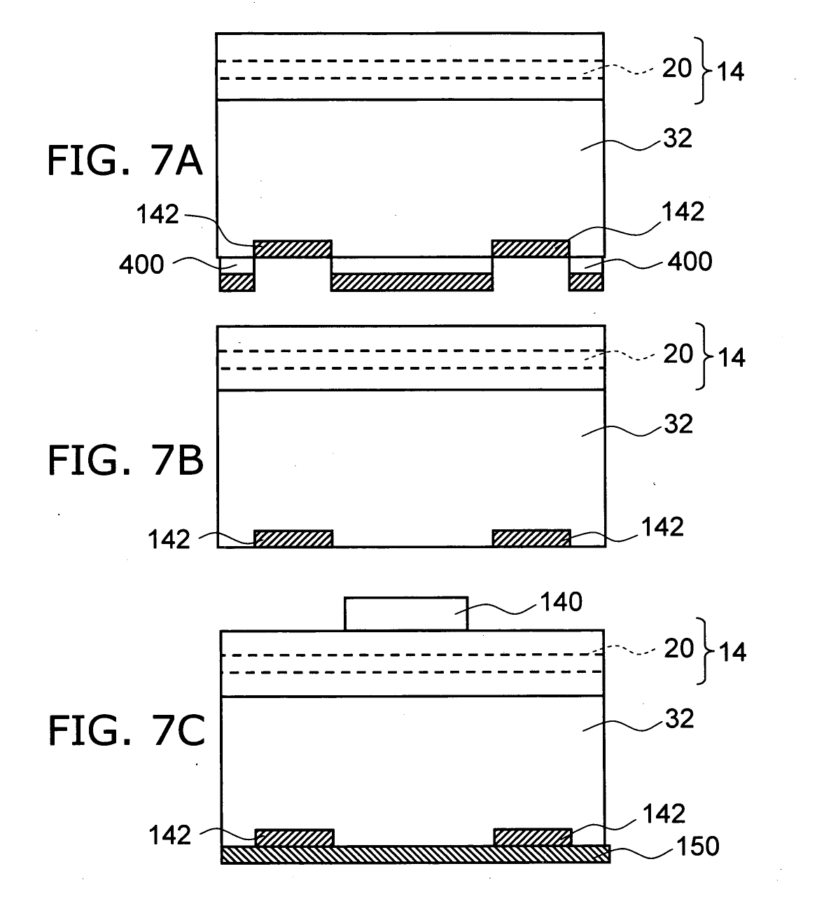

Next, as shown in FIG. 7A, electrode material is sputtered or vapor deposited on the rear side of the GaP substrate 32. The electrode material may be metal of gold (Au) containing 5 atomic % zinc (Zn). The thickness of the electrode material is made equal to the depth of the groove G.

Next, as shown in FIG. 7B, the mask 400 is removed using ammonium fluoride. As a result, the electrode material deposited on the mask 400 is removed with the mask to leave a wafer configured so that the electrode 142 is embedded in the rear side of the GaP substrate 32 as shown in FIG. 7B.

Next, as shown in FIG. 7C, gold (Au) or the like is deposited on the rear side of the GaP substrate 32 to form a conductive reflecting film 150. An electrode 140 is formed on top of the light emitting layer 14. Finally, chips are separated by dicing or otherwise to result in a semiconductor light emitting device of this embodiment.

### Second Embodiment

Next, as a second embodiment of the invention, description will be made on a semiconductor light emitting device in which electrode contact is formed at the side face of steps provided on the rear side of a transparent substrate.

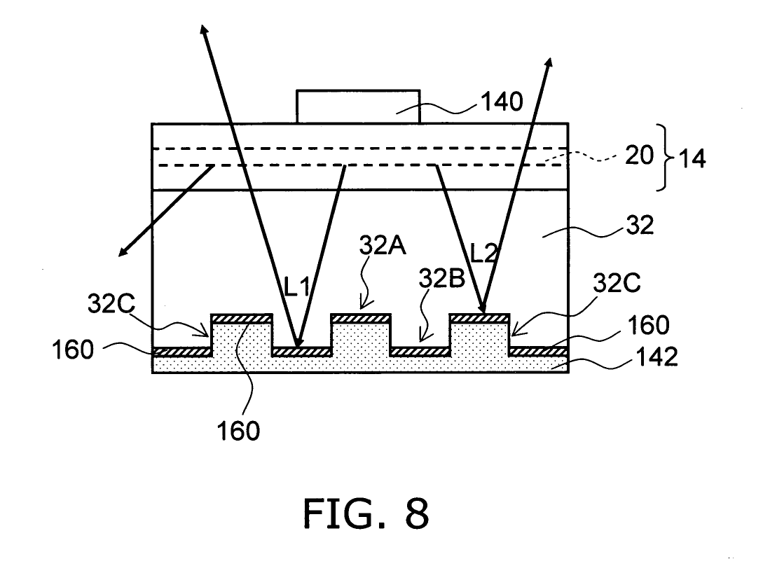

FIG. 8 is a schematic view illustrating the cross-sectional structure of a semiconductor light emitting device according to this embodiment. More specifically, this semiconductor light emitting device has again a substrate 32 and a light emitting layer 14 provided thereon. The substrate 32 is made of material being transparent to the light emitted from the light emitting layer 14. An electrode 140 is provided on top of the light emitting layer 14. On the other hand, the rear side of the substrate 32 has steps, and another electrode 142 is provided so as to fill in the steps. In this embodiment again, one of the electrodes 140 and 142 is a p-side electrode, and the other is an n-side electrode.

The substrate 32 forms contact with the electrode 142 at the side face 32C of the steps. On the other hand, a reaction suppressing film 160 made of silicon oxide or silicon oxynitride, for example, is selectively provided on the bottom face 32A and top face 32B of the steps.

In other words, in this embodiment, the reaction suppressing film 160 is interposed at part of the interface between the substrate 32 and the electrode 142, and is not at the other part. The reaction suppressing film 160 is provided on the bottom face 32A and top face 32B of the steps, and serves to suppress alloying and diffusion between the electrode 142 and the substrate 32.

More specifically, if the electrode 142 is in direct contact with the substrate 32, dopant components contained in the electrode 142 may diffuse into the substrate 32 to form a high-concentration region, and/or the electrode 142 is alloyed with the substrate 32 to form an alloyed region. The high-concentration region and alloyed region absorb light emitted from the light emitting layer 14, thereby causing some loss.

In contrast, according to this embodiment, by partial interposition of the reaction suppressing film 160, formation of the high-concentration region and alloyed region can be prevented at the bottom face 32A and top face 32B of the rear face of the substrate 32 to reduce absorption of light while maintaining the current injection path. As a result, the light extraction efficiency can be increased.

On the other hand, the substrate 32 is in contact with the electrode 142 at the side face 32C of the steps to form an alloyed region or high-concentration region at the contact area. Since the alloyed region or high-concentration region, although having high absorptance for light emitted from the light emitting layer 14, is formed at the side face 32C of the steps, it does not receive much light from the light emitting layer 14. That is, the alloyed region or high-concentration region can hardly be seen from the light emitting layer 14 because it is formed at the side face 32C of the steps. Much of light L1, L2 emitted downward from the light emitting layer 14 is reflected at the bottom face 32A and top face 32B of the steps with high efficiency and can be extracted outside via the side face of the substrate 32 and the top face of the device. As a result, light from the light emitting layer 14 can be caused to reflect upward with high efficiency while sufficiently ensuring electrode contact on the rear face of the substrate 32, thereby increasing the light extraction efficiency. In other words, this embodiment can sufficiently ensure contact between the substrate 32 and the electrode 142 since the contact area can be increased depending on the area of the side face 32C of the steps without decreasing the light reflecting area on the rear face of the substrate 32.

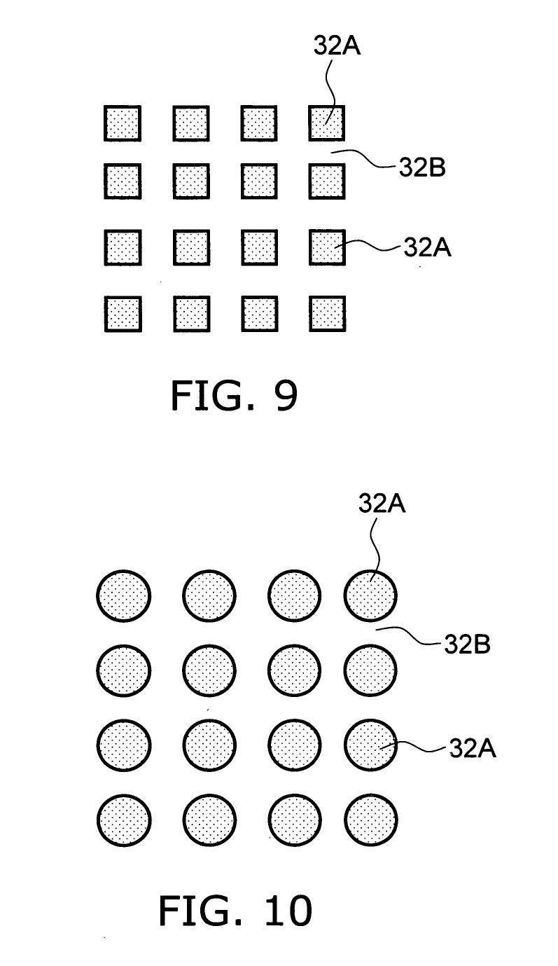

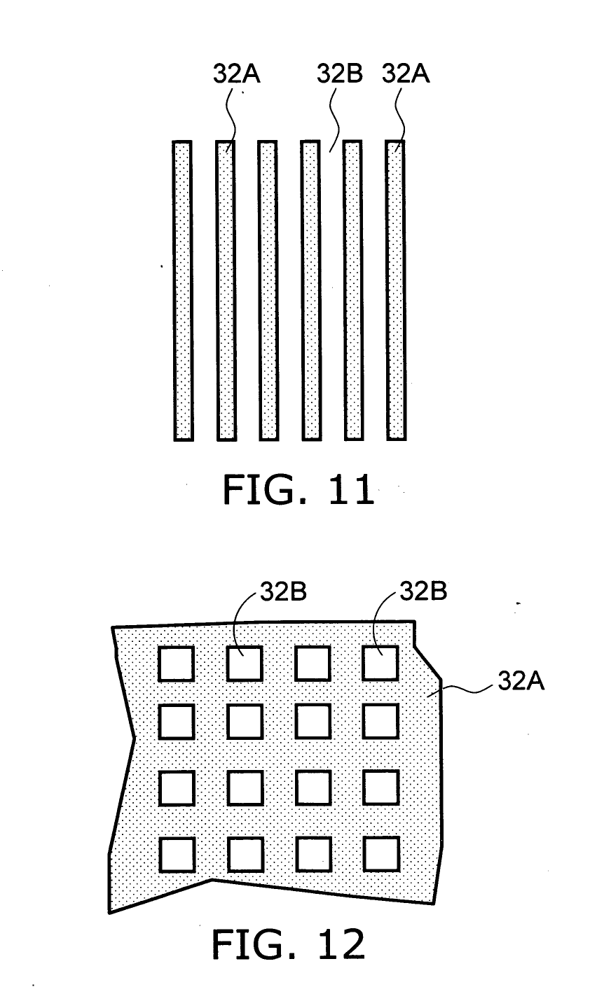

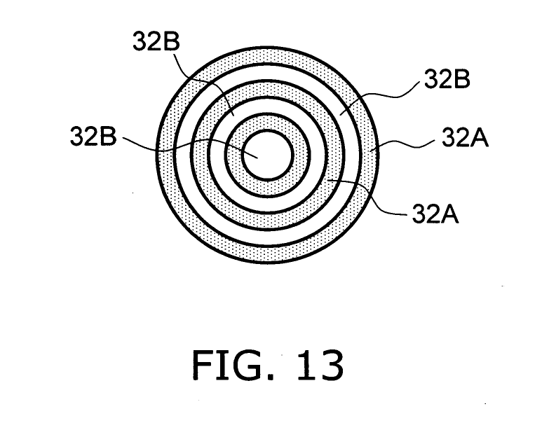

The steps in this embodiment may have various types of planar pattern configuration and size as appropriate, including examples shown in FIGS. 9 to 13. In forming the steps, trenches and/or holes of various shapes may be formed on the rear side of the substrate 32 as appropriate. Alternatively, one or more protrusions may be formed by etching the rear face of the substrate 32.

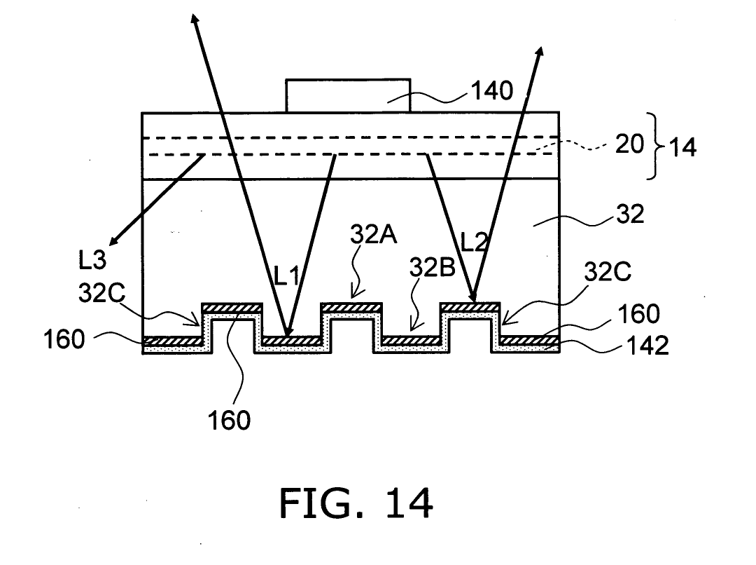

In addition, as illustrated in FIG. 14, the electrode 142 in this embodiment does not need to completely fill in the steps or trenches provided on the rear face of the substrate 32. That is, a thin-film electrode 142 may be provided along the bottom face 32A, side face 32C, and top face 32B of the steps.

The reaction suppressing film 160 in this embodiment is preferably formed from material having low reactivity with the substrate 32 and the electrode 142. Such material may include various types of oxides, nitrides, and fluorides, for example. The reaction suppressing film 160 may be insulative, conductive, or semiconductive. For example, it can be formed from conductive material such as titanium nitride and tungsten nitride. The reaction suppressing film 160 may have a monolayer structure made of a single film of such material, or a multilayer structure made of a plurality of laminated films.

When the reaction suppressing film 160 is highly reflective like a dielectric DBR (distributed Bragg reflector) or a film of molybdenum (Mo) or titanium (Ti), reflection of light L1, L2 at the reaction suppressing film 160 is predominant. On the other hand, when the reaction suppressing film 160 is made of transparent material such as silicon oxide or silicon oxynitride, reflection of light L1, L2 at the surface of the electrode 142 is predominant.

Next, a method of manufacturing a semiconductor light emitting device of this embodiment will be described.

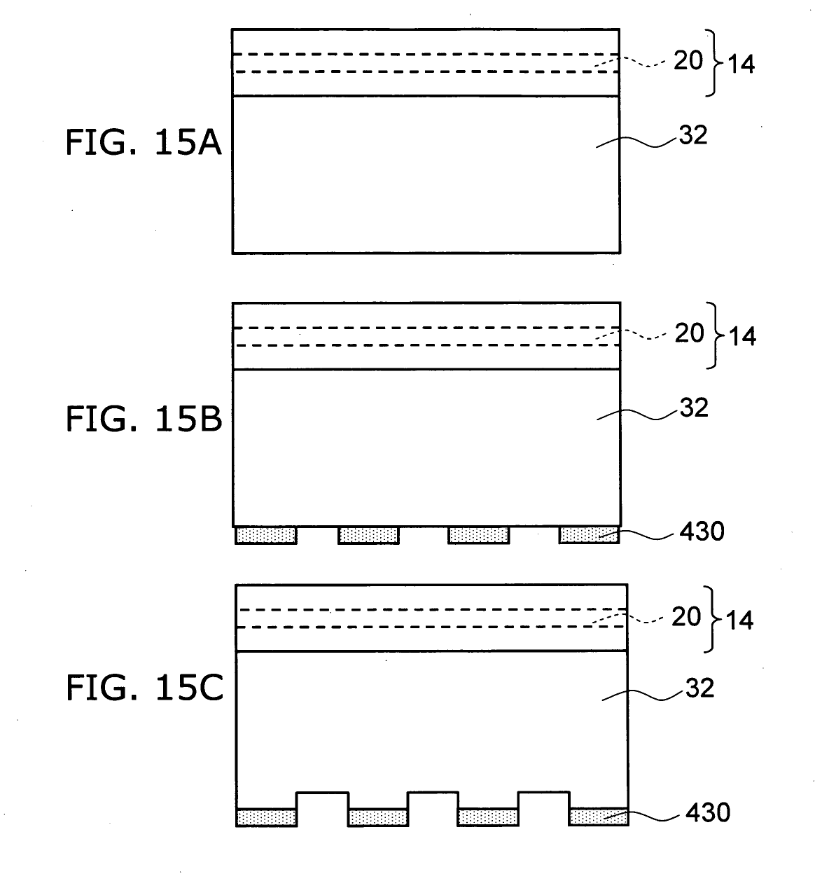

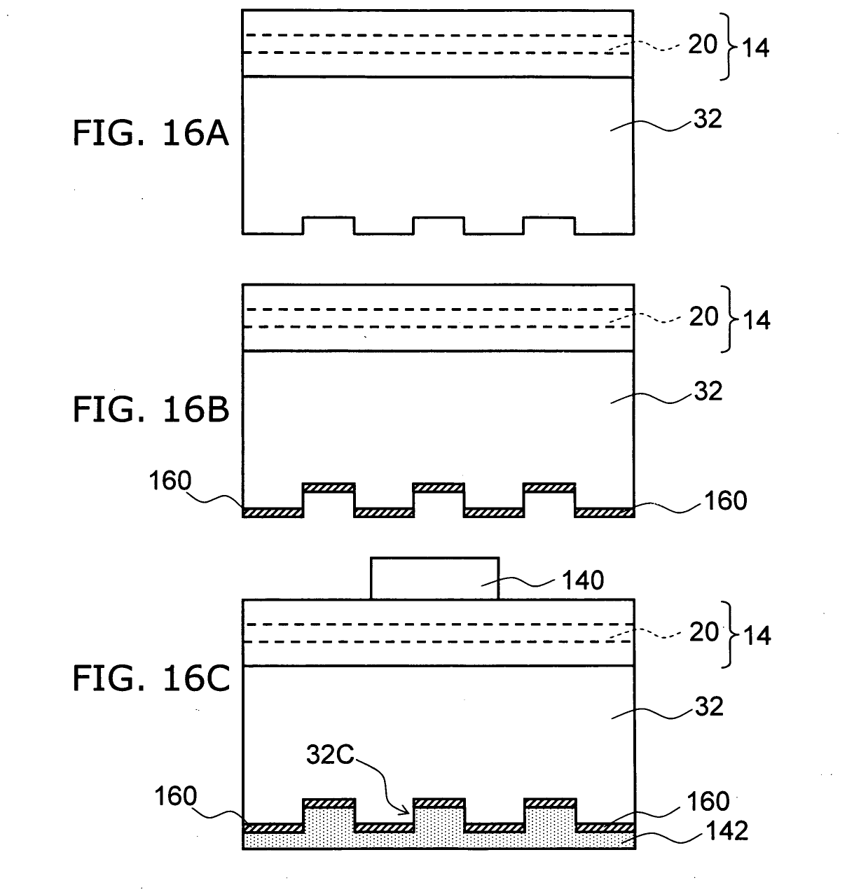

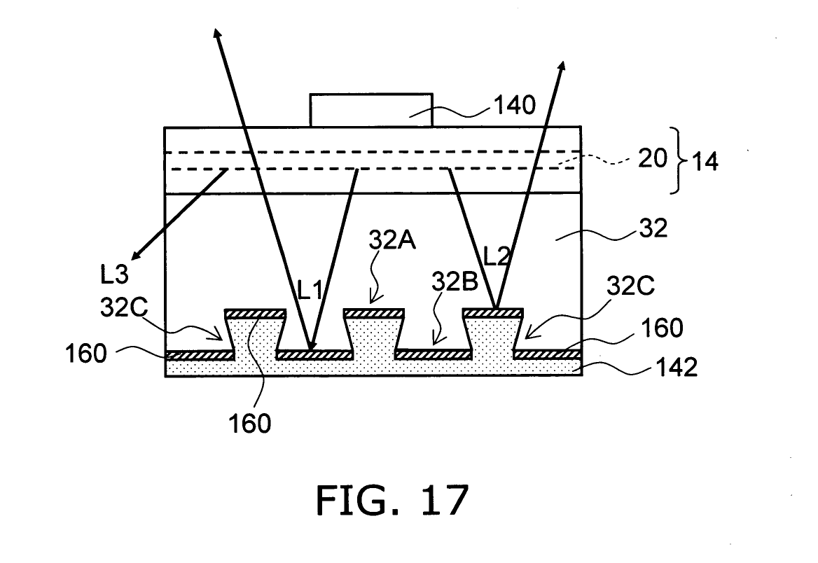

FIGS. 15A to 16C are process cross-sectional views showing a method of manufacturing a semiconductor light emitting device of this embodiment.

First, as shown in FIG. 15A, a laminated body including a light emitting layer 14 is formed on the substrate 32. The detailed process is as described above with reference to FIGS. 5A to 6A, for example.

Subsequently, as shown in FIG. 15B, a mask 430 is formed on the rear face of the substrate 32. The mask 430 has apertures at locations where steps are to be formed. Photoresist, for example, can be used for the mask.

Next, as shown in FIG. 15C, the rear face of the substrate 32 is etched. Etching methods including dry etching such as RIE (Reactive Ion Etching) or wet etching can be used as appropriate.

Subsequently, as shown in FIG. 16A, the mask 430 is removed.

Next, as shown in FIG. 16B, a reaction suppressing film 160 is formed. When a silicon oxide film is formed as the reaction suppressing film 160, for example, it can be formed by CVD method and the like.

Next, as shown in FIG. 16C, an electrode 142 is formed by depositing metal material on top of the reaction suppressing film 160. Another electrode 140 is formed on the surface of the light emitting layer 14. Heat treatment (sintering) can be applied as appropriate to form a high-concentration region and/or alloyed region at the interface between the electrodes 140, 142 and the semiconductor layer, thereby reducing contact resistance. That is, the substrate 32 reacts with the electrode 142 at the side face 32C of the steps to form a high-concentration region and/or alloyed region. In spite of this, reaction between the substrate 32 and the electrode 142 is suppressed in the area where the reaction suppressing film 160 is provided, and such a high-concentration region and/or alloyed region having high absorptance is not formed. According to the method as described above, the semiconductor light emitting device of this embodiment is completed.

FIG. 17 is a schematic cross-sectional view showing a second example of the semiconductor light emitting device of this embodiment.

In this example, the steps are formed in the so-called “inverted mesa” configuration. More specifically, the side face 32C of the steps is inclined relative to the major surface of the substrate 32 to have an “overhang” at the top face 32B. When the steps are viewed from the light emitting layer 14 side, the side face 32C of the steps is largely hidden, and only the bottom face 32A and top face 32B of the steps can be seen.

Formation of such steps can more effectively reduce absorption of light in the high-concentration region and/or alloyed region formed at the side face 32C of the steps.

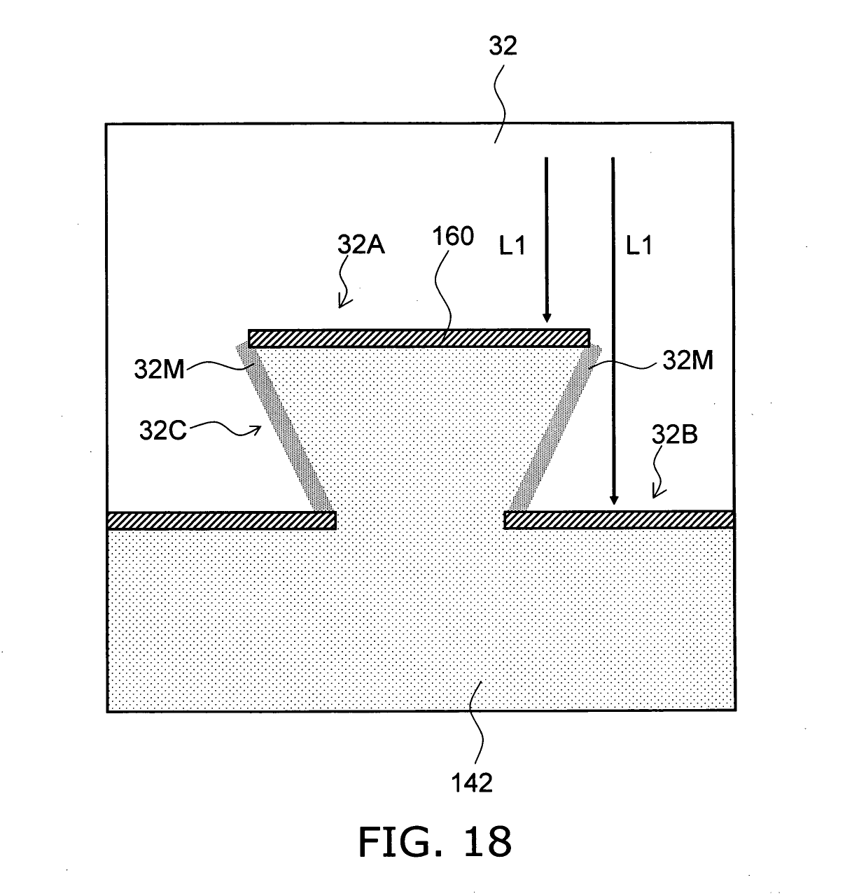

FIG. 18 is an enlarged cross-sectional view of a relevant part intended for illustrating the function in this example.

More specifically, reaction between the substrate 32 and the electrode 142 causes high concentration or alloying at the side face 32C of the step, thereby forming an absorbing region 32M having high absorptance for light from the light emitting layer 14.

In this connection, in this example, the absorbing region 32M is hidden behind the bottom face 32A of the step as viewed from the light emitting layer 14 side. That is, light L1 emitted downward from the light emitting layer 14 is not incident on the absorbing region 32M, but is incident on the bottom face 32A or top face 32B of the step and reflected with high efficiency. In other words, by hiding the absorbing region 32M behind the step, the loss due to absorption can be reduced and the light extraction efficiency can be further increased.

Such an “inverted mesa” step can be formed, for example, by appropriately selecting etchant for wet etching in the etching process for the substrate 32 as described above with reference to FIG. 15C. Alternatively, in using anisotropic etching such as RIE and ion milling, the step can be formed by appropriately selecting the wafer angle relative to the etching beam.

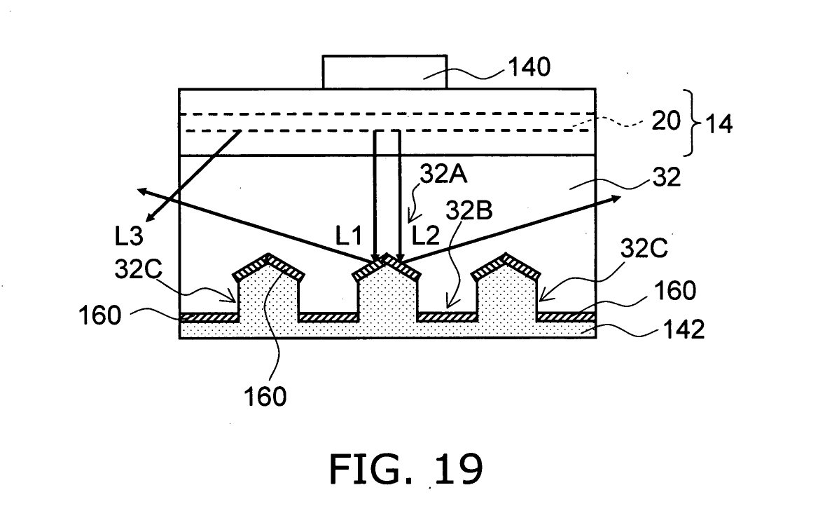

FIG. 19 is a schematic cross-sectional view showing a third example of the semiconductor light emitting device of this embodiment.

In this example, the bottom face 32A of the steps is not flat but beveled. More specifically, the bottom face 32A of the steps is covered with bevels so as to be convex toward the light emitting layer 14. According to this configuration, light L1, L2 emitted downward from the light emitting layer 14 can be reflected toward the side face of the substrate 32.

In general, the light emitting layer 14 includes highly absorptive layers such as the active layer 20. In this connection, according to this example, light emitted from the light emitting layer 14 can be passed through the transparent substrate 32 and extracted outside from the side face thereof. As a result, the loss due to absorption can be reduced and the light extraction efficiency can be further increased.

The shape of the bevels at the bottom face 32A of the steps in this example can be appropriately determined depending on the shape of the steps. For example, when circular holes are provided on the rear face of the substrate 32 for forming the steps, the bottom face thereof may be formed in a substantially conical shape. When striped trenches are formed on the rear face of the substrate 32, a pair of bevels extending longitudinally along the trench may be provided.

The bottom face 32A of the steps does not necessarily need to be a combination of flat bevels, but may be a curved surface being convex toward the light emitting layer 14.

The method of forming the bevel or curved surface at the bottom face 32A of the steps may include, for example, using the surface orientation dependence of etching rate in wet etching to expose a particular crystal face.

Alternatively, a blade having a V-shaped tip can be used to cut a groove for forming the bevel or curved surface. Furthermore, scanning machining by a laser beam can be used to form the bevel or curved surface.

In addition, this example can also use the “inverted mesa” structure of the steps as described above with reference to FIGS. 17 and 18. This can reduce absorption of light at the side face 32C and further increase the light extraction efficiency.

### Third Embodiment

Next, as a third embodiment of the invention, description will be made on a semiconductor light emitting device in which a reflecting film is selectively embedded in a transparent substrate.

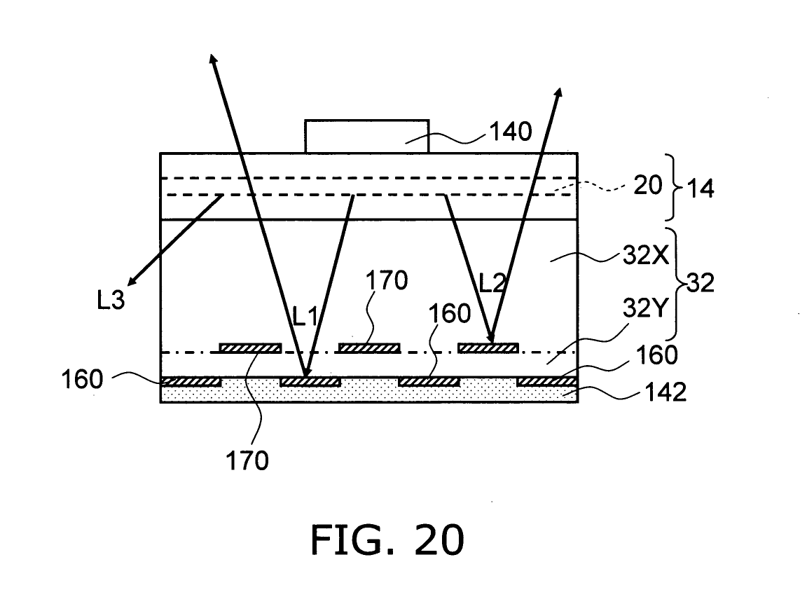

FIG. 20 is a schematic view showing the cross-sectional structure of a semiconductor light emitting device of this embodiment.

More specifically, this semiconductor light emitting device has again a substrate 32 and a light emitting layer 14 provided thereon. The substrate 32 is made of material being transparent to the light emitted from the light emitting layer 14. An electrode 140 is provided on top of the light emitting layer 14. On the other hand, a reaction suppressing film 160 is selectively provided on the rear side of the substrate 32, and another electrode 142 is provided so as to cover the reaction suppressing film 160. The reaction suppressing film 160, as described above in the second embodiment, serves to suppress formation of a high-concentration region and/or alloyed region due to the reaction between the substrate 32 and the electrode 142. In this embodiment again, one of the electrodes 140 and 142 is a p-side electrode, and the other is an n-side electrode.

In this embodiment, a reflecting film 170 is selectively embedded in the transparent substrate 32. The reflecting film 170 is selectively provided corresponding to the area where the substrate 32 is in direct contact with the electrode 142. That is, the reflecting film 170 is provided on the front side of the contact area between the substrate 32 and the electrode 142 so as to hide the contact area. According to this configuration, absorption of light in the contact area between the substrate 32 and the electrode 142 can be prevented.

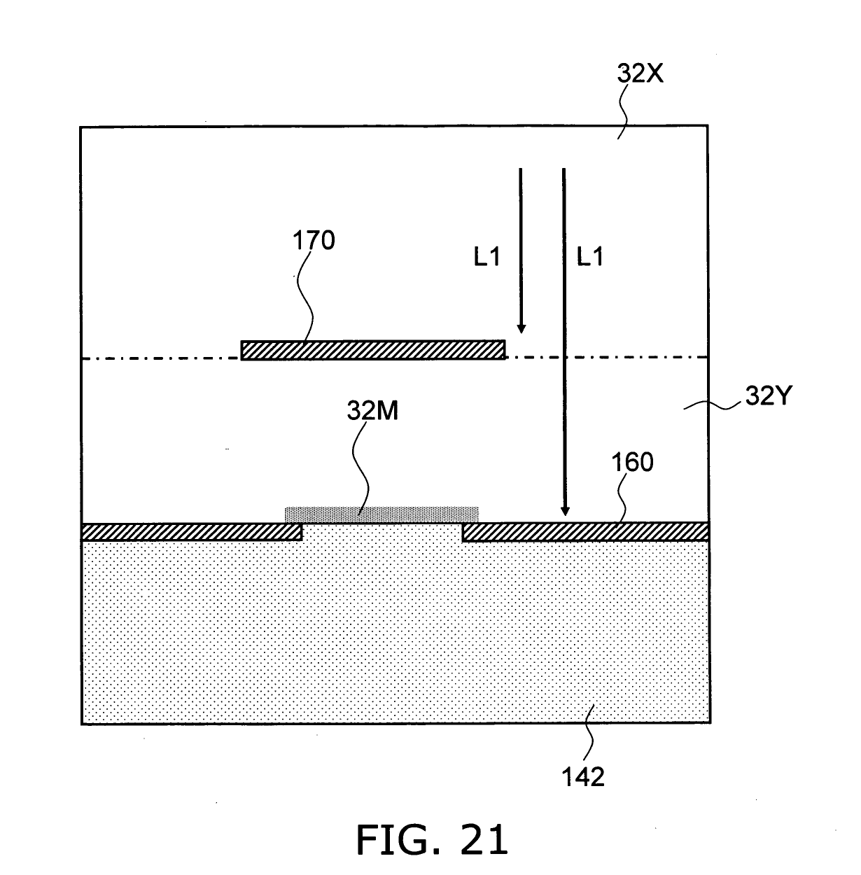

FIG. 21 is a partially enlarged cross-sectional view of the semiconductor light emitting device of this embodiment.

An absorbing region 32M having high absorptance is formed by diffusion and/or alloying in the area where the substrate 32 is in direct contact with the electrode 142. In this connection, in this embodiment, the light reflecting film 170 is embedded above the absorbing region 32M, and thereby light L1 from the light emitting layer 14 can be reflected without absorption. As a result, the loss due to absorption can be reduced and the light extraction efficiency can be increased.

The light reflecting film 170 can be formed from a DBR using dielectric or semiconductor, for example. That is, a Bragg reflector made of two types of alternately laminated layers having different refractive indices can be used.

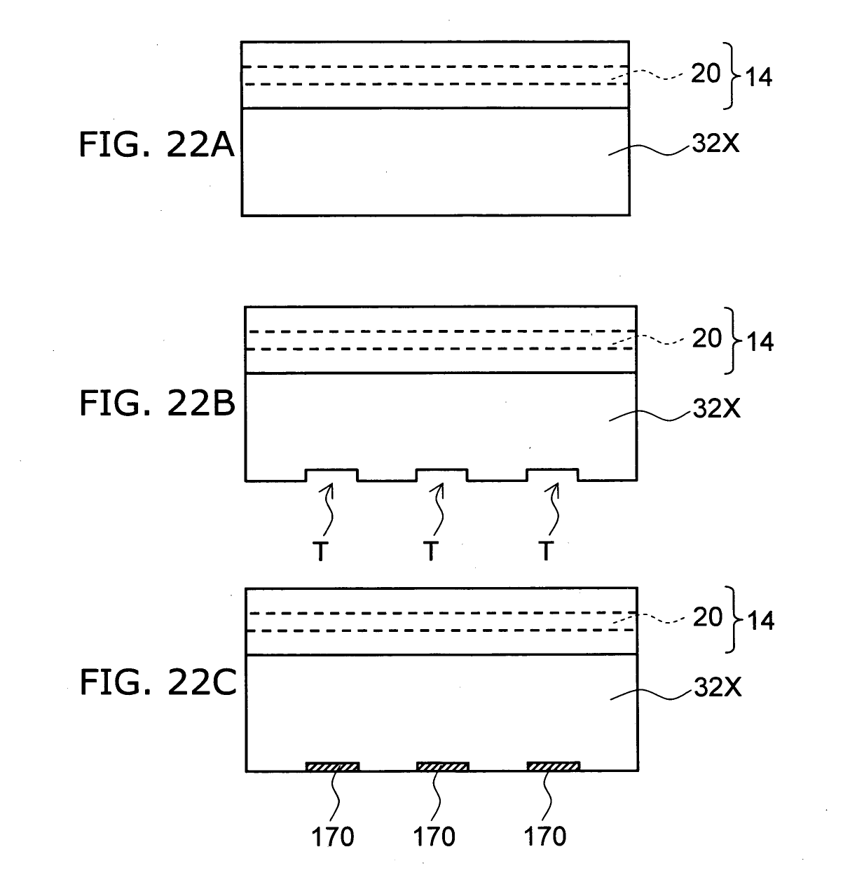

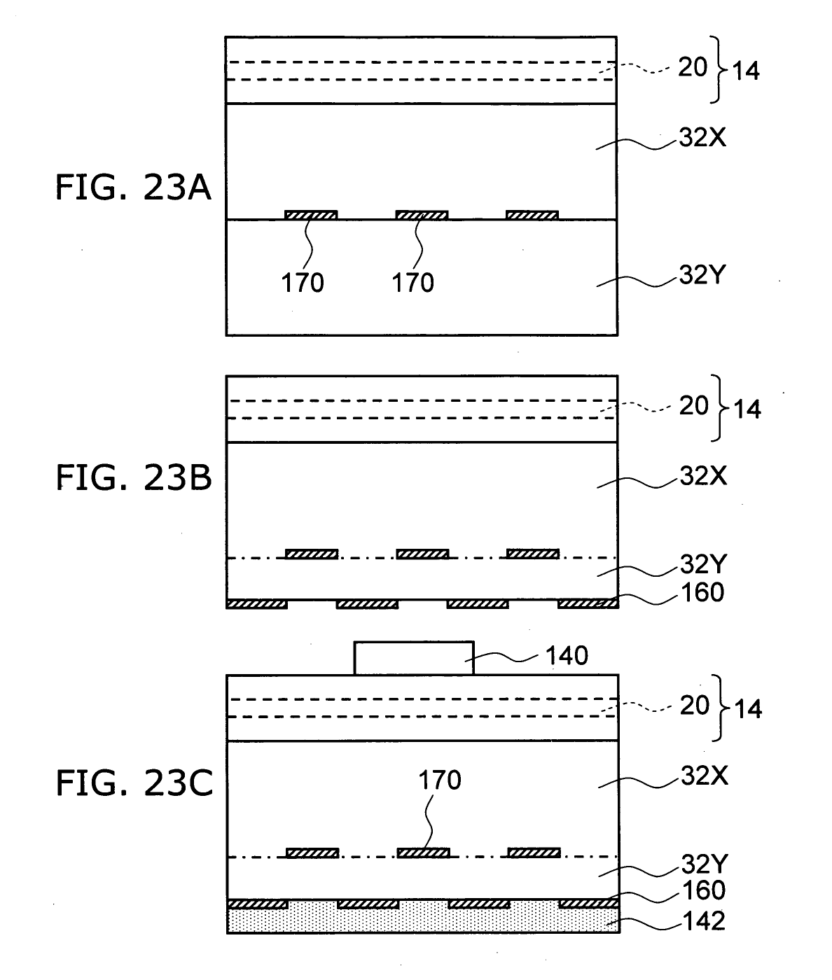

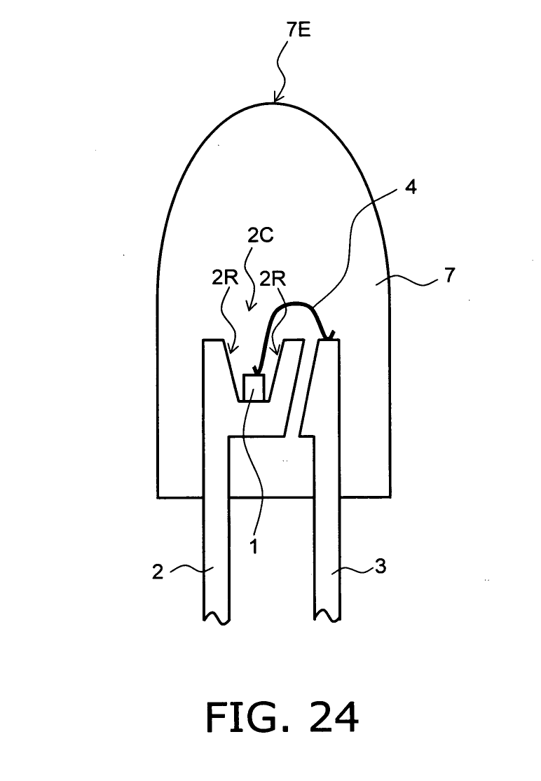

FIGS. 22A to 23C are process cross-sectional views illustrating a method of manufacturing a semiconductor light emitting device of this embodiment.

First, as shown in FIG. 22A, a laminated body including a light emitting layer 14 is formed on the substrate 32X. The detailed process is again as described above with reference to FIGS. 5A to 6A, for example.

Subsequently, as shown in FIG. 22B, trenches T are formed on the rear face of the substrate 32X. The detailed process is as described above with reference to FIGS. 15B to 16A, for example.

Next, as shown in FIG. 22C, the trench T is filled with a light reflecting film 170. The detailed process is as described above with reference to FIGS. 6C to 7B. When a dielectric multilayer, for example, is used for the light reflecting film 170, the CVD or sputtering method is used to alternately laminate two types of dielectric films for filling in the trench T.

Next, as shown in FIG. 23A, a substrate 32Y is laminated on the rear face of the substrate 32X. The detailed process is as described above with reference to FIG. 5B. To the rear face of the substrate 32X made of GaP, for example, another substrate 32Y also made of GaP can be bonded by thermocompression.

Subsequently, as shown in FIG. 23B, the rear face of the substrate 32Y is polished to adjust its thickness. Furthermore, a reaction suppressing film 160 is selectively formed. For example, after a reaction suppressing film 160 is uniformly formed on the rear face of the substrate 32Y, a mask having a predetermined pattern is formed to selectively etch the reaction suppressing film 160 in the area not covered with the mask. In this way, the reaction suppressing film 160 can be selectively formed as shown in FIG. 23B.

Next, as shown in FIG. 23C, an electrode 142 is formed by depositing metal material on top of the reaction suppressing film 160. Another electrode 140 is formed on the surface of the light emitting layer 14. Heat treatment (sintering) can be applied as appropriate to form a high-concentration region and/or alloyed region at the interface between the electrodes 140, 142 and the semiconductor layer, thereby reducing contact resistance. That is, the substrate 32Y reacts with the electrode 142 to form a high-concentration region and/or alloyed region. In spite of this, as described above with reference to the second embodiment, reaction between the substrate 32Y and the electrode 142 is suppressed in the area where the reaction suppressing film 160 is provided, and such a high-concentration region and/or alloyed region having high absorptance is not formed. According to the method as described above, the semiconductor light emitting device with the light reflecting film 170 being embedded in the transparent substrate 32 is completed.

### Fourth Embodiment

Next, as a fourth embodiment of the invention, a semiconductor light emitting apparatus equipped with the semiconductor light emitting device will be described. More specifically, a semiconductor light emitting apparatus with high brightness can be obtained by packaging the semiconductor light emitting device described above with reference to the first to third embodiments on a lead frame, mounting board, or the like.

FIG. 24 is a schematic cross-sectional view showing a semiconductor light emitting apparatus of this embodiment. More specifically, the semiconductor light emitting apparatus of this example is a resin-sealed semiconductor light emitting apparatus called the “bullet-shaped” type.

A cup portion 2C is provided on top of a lead 2. The semiconductor light emitting device 1 is mounted on the bottom face of the cup portion 2C with an adhesive or the like. It is connected to another lead 3 using a wire 4. The inner wall of the cup portion 2C constitutes a light reflecting surface 2R, which reflects the light emitted from the semiconductor light emitting device 1 and allows the light to be extracted above. In this example, in particular, the light emitted from the side face and the like of the transparent substrate of the semiconductor light emitting device 1 can be reflected by the light reflecting surface 2R and extracted above.

The periphery of the cup portion 2C is sealed with transparent resin 7. The light extraction surface 7E of the resin 7 forms a condensing surface, which can condense the light emitted from the semiconductor light emitting device 1 as appropriate to achieve a predetermined light distribution.

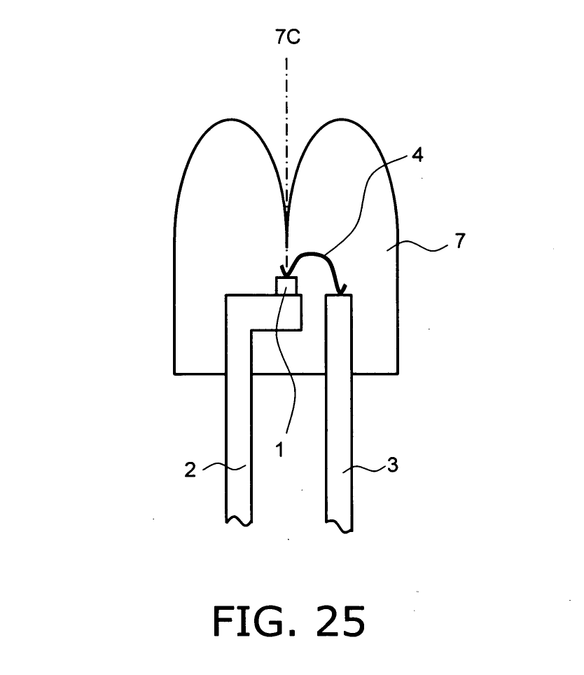

FIG. 25 is a schematic cross-sectional view showing another example of the semiconductor light emitting apparatus. More specifically, in this example, the resin 7 sealing the semiconductor light emitting device 1 has rotational symmetry about its optical axis 7C. It is shaped as being set back and converged toward the semiconductor light emitting device 1 at the center. The resin 7 of such shape results in light distribution characteristics where light is scattered at wide angles.

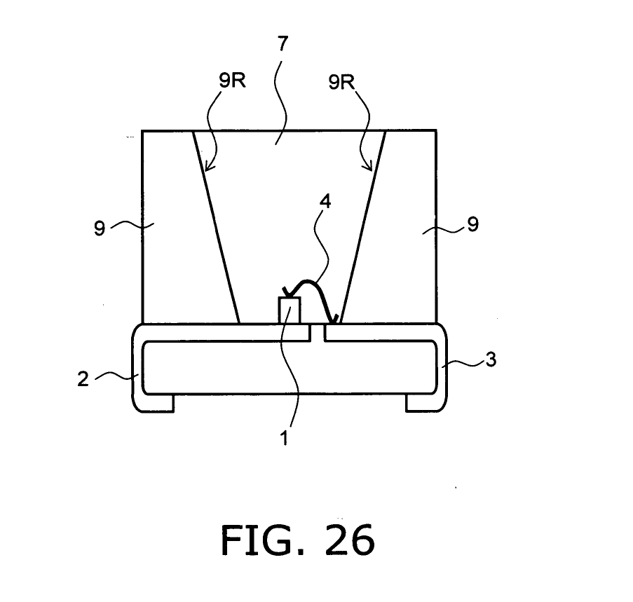

FIG. 26 is a schematic cross-sectional view showing still another example of the semiconductor light emitting apparatus. More specifically, this example is called the “surface mounted” type. The semiconductor light emitting device 1 is mounted on a lead 2, and connected to another lead 3 using a wire 4. These leads 2 and 3 are molded in first resin 9. The semiconductor light emitting device 1 is sealed with second transparent resin 7. The first resin 9 has an enhanced light reflectivity by dispersion of fine particles of titanium oxide, for example. Its inner wall 9R acts as a light reflecting surface to guide the light emitted from the semiconductor light emitting device 1 to the outside. That is, the light emitted from the side face and the like of the transparent substrate can be extracted above.

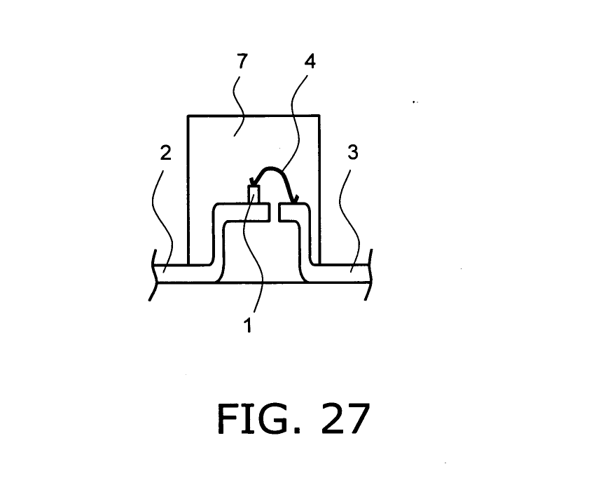

FIG. 27 is a schematic cross-sectional view showing still another example of the semiconductor light emitting apparatus. More specifically, this example is also what is called the “surface mounted” type. The semiconductor light emitting device 1 is mounted on a lead 2, and connected to another lead 3 using a wire 4. The tips of these leads 2 and 3, together with the semiconductor light emitting device 1, are molded in transparent resin 7.

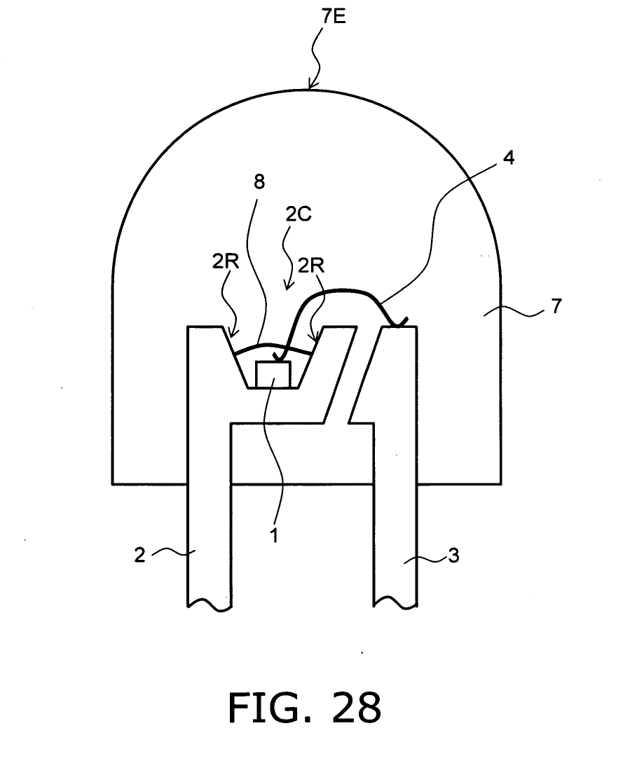

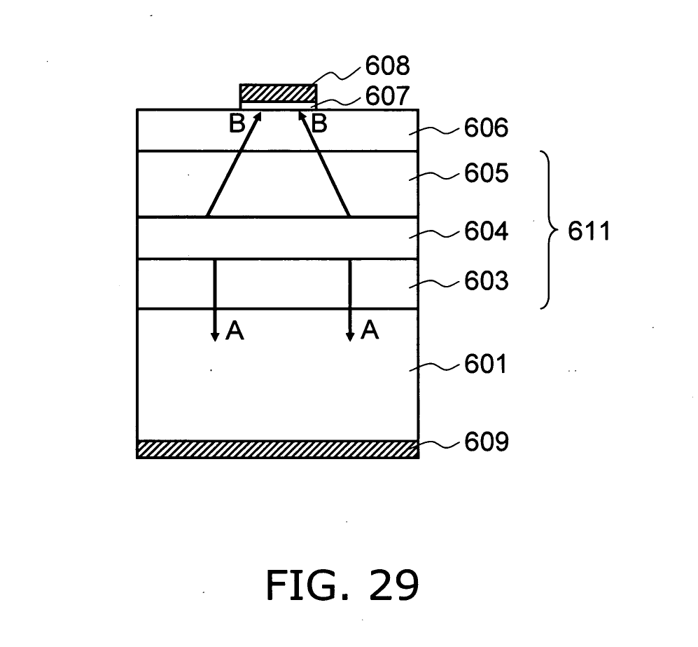

FIG. 28 is a schematic cross-sectional view showing still another example of the semiconductor light emitting apparatus. In this example, a structure similar to that described above with reference to FIG. 24 is used. In addition, the semiconductor light emitting device 1 is covered with phosphor 8. The phosphor 8 serves to absorb the light emitted from the semiconductor light emitting device 1 and convert its wavelength. For example, ultraviolet or blue primary light is emitted from the semiconductor light emitting device 1. The phosphor 8 absorbs this primary light and emits secondary light having different wavelengths such as red and green. For example, three kinds of phosphor 8 may be mixed, and the phosphor 8 may absorb ultraviolet radiation emitted from the semiconductor light emitting device 1 to emit white light composed of blue, green, and red light.

The phosphor 8 may be applied to the surface of the semiconductor light emitting device 1, or may be contained in the resin 7.

In any semiconductor light emitting apparatus shown in FIGS. 24 to 28, a semiconductor light emitting apparatus with high brightness can be offered by providing the semiconductor light emitting device described above with reference to the first to third embodiments to extract light from the top and/or side faces of the semiconductor light emitting device 1 with high efficiency.

Embodiments of the invention have been described with reference to examples. However, the invention is not limited to these examples. For example, various variations of the semiconductor light emitting device and the semiconductor light emitting apparatus with respect to their structure and the like are also encompassed within the scope of the invention.

For example, any details of the layered structure constituting the semiconductor light emitting device modified as appropriate by those skilled in the art are also encompassed within the scope of the invention, as long as they include the subject matter of the invention. For instance, the active layer may be made of various materials besides InGaAlP-based material, including GaₓIn₁₋ₓAs_{y}N_{1-y}-based (0≦x≦1, 0≦y<1), AlGaAs-based, and InGaAsP-based materials. Similarly, the cladding layers and optical guide layer may also be made of various materials.

In addition, the wafer bonding described as a typical example of the method of manufacturing an LED having a light-transmitting substrate may also be applied to conventionally known LEDs such as AlGaAs-based LEDs in which the transparent substrate is obtained by thick epitaxial growth.

Any shape and size of the semiconductor light emitting device modified as appropriate by those skilled in the art are also encompassed within the scope of the invention, as long as they include the subject matter of the invention.

Furthermore, a semiconductor light emitting device and a semiconductor light emitting apparatus obtained from any combination of two or more of the embodiments of the invention are also encompassed within the scope of the invention. More specifically, for example, a semiconductor light emitting device and a semiconductor light emitting apparatus obtained by combining the first embodiment of the invention with one of the second and third embodiments of the invention are also encompassed within the scope of the invention.

Any other semiconductor light emitting devices and semiconductor light emitting apparatuses that can be modified and implemented as appropriate by those skilled in the art on the basis of the semiconductor light emitting devices and semiconductor light emitting apparatuses described above as the embodiments of the invention also belong to the scope of the invention.

1. A semiconductor light emitting device comprising:
a substrate having first and second major surfaces and being transparent to light in a first wavelength band;
a light emitting layer provided above the first major surface of the substrate, the light emitting layer emitting light in the first wavelength band; and
an ohmic electrode selectively embedded on the second major surface of the substrate and having a surface substantially coplanar with the second major surface.

2. A semiconductor light emitting device according to claim 1, further comprising a metal film provided to cover the second major surface of the substrate and the surface of the ohmic electrode.

3. A semiconductor light emitting device according to claim 2, wherein the ohmic electrode and the metal film contain different materials.

4. A semiconductor light emitting device according to claim 2, wherein a material constituting the metal film is less reactive to the substrate than a material constituting the ohmic electrode.

5. A semiconductor light emitting device according to claim 2, wherein reflectance of the metal film for light emitted from the light emitting layer is greater than reflectance of the ohmic electrode for the light emitted from the light emitting layer.

6. A semiconductor light emitting device according to claim 1, wherein
the substrate comprises GaP, and
the light emitting layer comprises InGaAlP.

7. A semiconductor light emitting device comprising:
a substrate having first and second major surfaces and being transparent to light in a first wavelength band, the second major surface having steps with bottom, side, and top faces;
a light emitting layer provided above the first major surface of the substrate, the light emitting layer emitting light in the first wavelength band; and
an electrode selectively provided in contact with the side face of the steps.

8. A semiconductor light emitting device according to claim 7, wherein a reaction suppressing film is provided between the bottom face of the steps and the electrode and between the top face of the steps and the electrode, the reaction suppressing film suppressing reaction between the substrate and the electrode.

9. A semiconductor light emitting device according to claim 7, wherein the electrode forms ohmic contact with the substrate at the side face of the steps.

10. A semiconductor light emitting device according to claim 7, wherein the electrode forms a surface substantially flat above the second major surface by filling in the steps.

11. A semiconductor light emitting device according to claim 7, wherein the electrode is formed as a thin film along the bottom, side, and top faces of the steps.

12. A semiconductor light emitting device according to claim 7, wherein
the side face of the steps is inclined relative to the second major surface, and
the top face of the steps has an overhang with respect to the bottom face of the steps.

13. A semiconductor light emitting device according to claim 7, wherein the bottom face of the steps has a bevel or curved surface to be convex toward the light emitting layer.

14. A semiconductor light emitting device according to claim 8, wherein reflectance of the reaction suppressing film for light emitted from the light emitting layer is greater than reflectance of the electrode for the light emitted from the light emitting layer.

15. A semiconductor light emitting device according to claim 7, wherein
the substrate comprises GaP, and
the light emitting layer comprises InGaAlP.

16. A semiconductor light emitting device according to claim 8, wherein the reaction suppressing film comprises a dielectric material.

17. A semiconductor light emitting device comprising:
a substrate having first and second major surfaces and being transparent to light in a first wavelength band;
a light emitting layer provided above the first major surface of the substrate, the light emitting layer emitting light in the first wavelength band;
an electrode provided on the second major surface of the substrate;
a reaction suppressing film selectively provided between the second major surface of the substrate and the electrode, the reaction suppressing film suppressing reaction between the substrate and the electrode; and
a light reflecting film selectively embedded in the substrate, the light reflecting film reflecting light in the first wavelength band directed toward the interface between the substrate and the electrode as viewed from the light emitting layer.

18. A semiconductor light emitting device according to claim 17, wherein the reaction suppressing film comprises a dielectric material.

19. A semiconductor light emitting device according to claim 17, wherein the electrode forms ohmic contact with the substrate at the interface with the substrate.

20. A semiconductor light emitting device according to claim 17, wherein
the substrate comprises GaP, and
the light emitting layer comprises InGaAlP.
